(19) United States
(12) Patent Application Publication
(10) Pub. No.: US 2026/0136670 A1
(43) Pub. Date: May 14, 2026

(54) ARRAY SUBSTRATE AND DISPLAY PANEL

(71) Applicant: Guangzhou China Star Optoelectronics Semiconductor Display Technology Co., LTd., Guangzhou (CN)

(72) Inventor: Fangmei LIU, Guangzhou (CN)

(73) Assignee: Guangzhou China Star Optoelectronics Semiconductor Display Technology Co., LTd., Guangzhou (CN)

(21) Appl. No.: 19/017,361

(22) Filed: Jan. 10, 2025

(30) Foreign Application Priority Data
Nov. 8, 2024 (CN) 202411598972.5

(51) Int. Cl. H10D 86/40; H10D 86/60

(52) U.S. Cl. CPC H10D 86/441; H10D 86/60

(57) ABSTRACT

An array substrate and a display panel are provided. The array substrate includes a substrate, a first conductive layer, a first insulating layer, a second conductive layer, and an active layer. The second conductive layer includes a first auxiliary electrode and a second auxiliary electrode disposed at intervals. The first gap is provided between the first auxiliary electrode and the second auxiliary electrode, and the first gap may define a length of a channel portion of the active layer. The source contact portion of the active layer and the first auxiliary electrode extend into the first via hole of the first insulating layer, and is electrically connected to the source of the first conductive layer.

### CROSS-REFERENCE TO RELATED APPLICATIONS

This application claims priority to Chinese Patent Application No. 202411598972.5 filed on Nov. 8, 2024. The disclosure of the aforementioned application is incorporated herein by reference in its entirety.

### TECHNICAL FIELD

The present disclosure relates to the technical field of display, in particular to an array substrate and a display panel.

### BACKGROUND

In the technical field of display, the thin film transistor (TFT) array substrate is an important part of the display panel. The preparation of the thin film transistor array substrate involves the use of a plurality of photo masks. The more photo masks are used, the longer the overall process flow of the thin film transistor array substrate is, the greater the difficulty is, and the higher the cost is. In order to reduce the number of photo masks used, the source and drain layer of the thin film transistor and the light shielding layer below the thin film transistor may share a metal layer. However, since the source and drain layers and the light shielding layer share a metal layer, the layout design space for the array substrate is limited, and it is difficult to achieve high pixels per inch (PPI).

### SUMMARY

The embodiments of the present disclosure provide an array substrate, including:
a substrate;
a first conductive layer disposed on a side of the substrate and including a source and a light shielding electrode disposed at intervals;
a first insulating layer disposed on a side of the first conductive layer away from the substrate and provided with a first via hole corresponding to the source;
a second conductive layer disposed on a side of the first insulating layer away from the substrate and including a first auxiliary electrode and a second auxiliary electrode disposed at intervals, where a first gap is provided between the first auxiliary electrode and the second auxiliary electrode; and
an active layer disposed on the side of the first insulating layer away from the substrate and including a source contact portion, a drain contact portion and a channel portion, where the channel portion is connected between the source contact portion and the drain contact portion, the source contact portion corresponds to the first auxiliary electrode and is electrically connected to the first auxiliary electrode, the drain contact portion corresponds to the second auxiliary electrode and is electrically connected to the second auxiliary electrode, and the channel portion corresponds to the first gap and is provided opposite to at least a part of the light shielding electrode;
a second insulating layer disposed on a side of the active layer away from the substrate; and
a third conductive layer disposed on a side of the second insulating layer away from the substrate and including a gate corresponding to the channel portion.

A part of the first auxiliary electrode and a part of the source contact portion are located in the first via hole and electrically connected to the source; and a channel length of the channel portion is equal to a width of the first gap.

The embodiments of the present disclosure further provide a display panel including the aforementioned array substrate.

### BRIEF DESCRIPTION OF THE DRAWINGS

To describe the technical solutions of the embodiments of the present disclosure or the prior art more clearly, the following briefly introduces are given to the accompanying drawings used in the description of the embodiments of the present disclosure or the prior art. Apparently, the accompanying drawings described below illustrate only some exemplary embodiments of the present disclosure, and persons skilled in the art may derive other drawings from the drawings without making creative efforts.

FIG. 1 is a schematic view of an array substrate provided by a preamble of an embodiment of the present disclosure.

FIG. 2 is a first schematic cross-sectional view of an array substrate provided by some embodiments of the present disclosure.

FIG. 3 is a second schematic cross-sectional view of the array substrate provided by some embodiments of the present disclosure.

FIG. 4 is a third schematic cross-sectional view of the array substrate provided by some embodiments of the present disclosure.

FIG. 5 is a fourth schematic cross-sectional view of the array substrate provided by some embodiments of the present disclosure.

FIG. 6 is a fifth schematic cross-sectional view of the array substrate provided by some embodiments of the present disclosure.

### DETAILED DESCRIPTION

The following description of every embodiment with reference to the accompanying drawings is used to exemplify a specific embodiment which may be carried out in the present disclosure. Directional terms mentioned in the present disclosure, such as “top”, “bottom”, “front”, “back”, “left”, “right”, “inside”, “outside”, “side” etc., are only used with reference to orientations of the accompanying drawings. Therefore, the used directional terms are intended to illustrate, but not to limit, the present disclosure. In the accompanying drawings, units with similar structures are indicated by the same reference numerals. In the accompanying drawings, the thicknesses of some layers and regions are exaggerated for clarity of understanding and ease of description. That is, the dimensions and thicknesses of each component shown in the accompanying drawings are arbitrarily shown, but the present disclosure is not limited thereto.

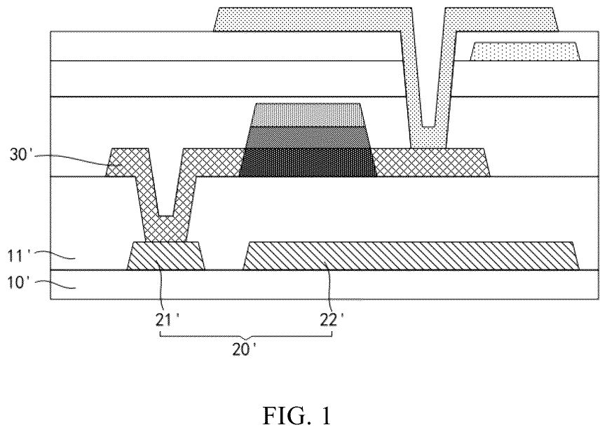

Referring to FIG. 1, FIG. 1 is a schematic view of an array substrate provided by a preamble of an embodiment of the present disclosure, an array substrate is provided. The array substrate includes a substrate 10′, a first conductive layer 20′, a first insulating layer 11′, and an active layer 30′ disposed on the substrate 10′. The first conductive layer 20′ includes a source 21′ and a light shielding electrode 22′ disposed at intervals. The active layer 30′ is in contact with and electrically connected to the source 21′ through a first via hole of the first insulating layer 11′. The source 21′ and the light shielding electrode 22′ are formed in the same metal layer, so that two masks may be saved, the cost may be reduced, and the parasitic capacitance may be reduced. However, since the source and drain layers and the light shielding electrode share a metal layer, the layout design space for the array substrate is limited, and it is difficult to achieve high PPI.

For this reason, the present disclosure provides an array substrate and a display panel.

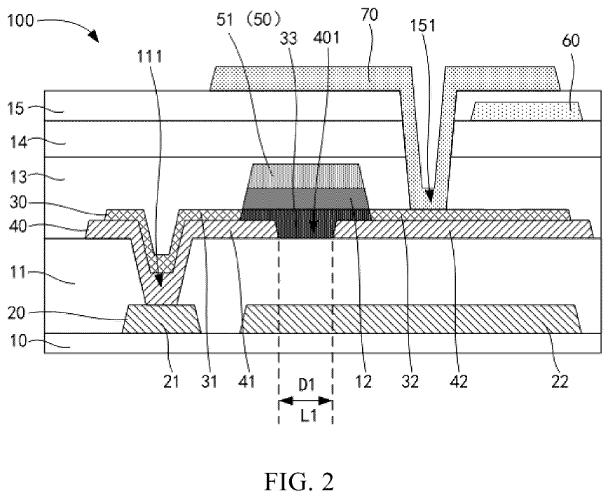

Referring to FIG. 2, FIG. 2 is a schematic diagram of a first cross-sectional structure of an array substrate provided by an embodiment of the present disclosure. Referring to FIG. 2, the array substrate 100 includes a substrate 10 and a first conductive layer 20, a first insulating layer 11, a second conductive layer 40, an active layer 30, a second insulating layer 12, and a third conductive layer 50 disposed on the substrate 10. The first conductive layer 20 is disposed on a side of the substrate 10, and includes a source 21 and a light shielding electrode 22 disposed at intervals. The first insulating layer 11 is disposed on a side of the first conductive layer 20 away from the substrate 10. The first insulating layer 11 is provided with a first via hole 111 corresponding to the source 21. The second conductive layer 40 is disposed on a side of the first insulating layer 11 away from the substrate 10, and includes a first auxiliary electrode 41 and a second auxiliary electrode 42 disposed at intervals. A first gap 401 is provided between the first auxiliary electrode 41 and the second auxiliary electrode 42.

The active layer 30 is disposed on a side of the first insulating layer 11 away from the substrate 10. The active layer 30 includes a source contact portion 31, a drain contact portion 32, and a channel portion 33. The channel portion 33 is connected between the source contact portion 31 and the drain contact portion 32. The source contact portion 31 corresponds to the first auxiliary electrode 41 and is electrically connected to the first auxiliary electrode 41. The drain contact portion 32 corresponds to the second auxiliary electrode 42 and is electrically connected to the second auxiliary electrode 42. The channel portion 33 corresponds to the first gap 401 and is provided opposite to at least a part of the light shielding electrode 22. It should be noted that the term “corresponding” in the present disclosure refers to the corresponding relationship between the two structures along the thickness direction of the array substrate 100. The second insulating layer 12 is disposed on a side of the active layer 30 away from the substrate 10. The third conductive layer 50 is disposed on a side of the second insulating layer 12 away from the substrate 10, and includes a gate 51 corresponding to the channel portion 33.

A part of the first auxiliary electrode 41 and a part of the source contact portion 31 are located in the first via hole 111 and electrically connected to the source 21. A channel length L1 of the channel portion 33 is equal to a width D1 of the first gap 401. The direction in which the width D1 is located refers to the direction in which the first auxiliary electrode 41 points towards the second auxiliary electrode 42. In this way, the first gap 401 between the first auxiliary electrode 41 and the second auxiliary electrode 42 may define the length L1 of the channel portion 33 of the active layer 30 to achieve a narrow channel, so that the size of the thin film transistor may be reduced, and the PPI may be increased to improve the problem that the layout design space for the array substrate 100 is limited and it is difficult to achieve high resolution. Further, the first auxiliary electrode 41 and the source contact portion 31 of the active layer 30 extend into the first via hole 111 of the first insulating layer 11 and are electrically connected to the source 21 of the first conductive layer 20. The first auxiliary electrode 41 located in the first via hole 111 may reduce the risk of disconnecting of the source contact portion 31 in the first via hole 111 caused by the source contact portion 31 climbing.

Specifically, referring to FIG. 2, the array substrate 100 further includes a first transistor disposed on the substrate 10. The first transistor may be a thin film transistor. The first transistor includes a source 21, an active layer 30, and a gate 51. The active layer 30 is disposed on a side of the source 21 away from the substrate 10. The gate 51 is disposed on a side of the active layer 30 away from the substrate 10. The active layer 30 includes a source contact portion 31, a drain contact portion 32, and a channel portion 33 connected between the source contact portion 31 and the drain contact portion 32, that is, the drain contact portion 32 and the source contact portion 31 are located on opposite sides of the channel portion 33. The gate 51 is provided facing the channel portion 33.

Alternatively, the substrate 10 may be a rigid substrate or a flexible substrate. In condition that the substrate 10 is a rigid substrate, it may include a rigid substrate such as a glass substrate, a quartz substrate, or a silicon wafer. In condition that the substrate 10 is a flexible substrate, the substrate 10 may include a flexible substrate such as a polyimide (PI) film or an ultra-thin glass film. In condition that the substrate 10 is polyimide film, moisture or oxygen may penetrate into the substrate 10 more easily than a glass substrate. To prevent this, a buffer layer having a single-layer or multilayer structure of silicon oxide or silicon nitride may be disposed on the substrate 10.

The first conductive layer 20 is disposed on the substrate 10. The first conductive layer 20 includes a source 21 and a light shielding electrode 22 that are spaced apart and insulated from each other. The light shielding electrode 22 is provided corresponding to at least the channel portion 33 to shield light for the channel portion 33 and reduce a photogenerated leakage current of the first transistor. The material of the first conductive layer 20 includes at least one of Mo, Al, Cu, Ti, or the like. The thickness of the first conductive layer 20 ranges from 1000 angstroms to 8000 angstroms, such as 1000 angstroms, 2000 angstroms, 3000 angstroms, 4000 angstroms, 5000 angstroms, 6000 angstroms, 7000 angstroms, 8000 angstroms, or the like.

The first insulating layer 11 covers the first conductive layer 20 and the substrate 10. The first insulating layer 11 covering the source 21 is formed with the first via hole 111 corresponding to the source 21. The first via hole 111 exposes a part of the source 21. The first via hole 111 penetrates the first insulating layer 11 to expose at least a part of the source 21. The material of the first insulating layer 11 includes silicon oxide (SiOx), silicon nitride (SiNx), or a laminated thin film of silicon oxide and silicon nitride. The thickness of the first insulating layer 11 ranges from 6000 angstroms to 10000 angstroms, such as 6000 angstroms, 7000 angstroms, 8000 angstroms, 9000 angstroms, 10000 angstroms, or the like.

The second conductive layer 40 is disposed on a side of the first insulating layer 11 away from the substrate 10. The second conductive layer 40 includes a first auxiliary electrode 41 and a second auxiliary electrode 42 disposed at intervals. There is a first gap 401 provided between the first auxiliary electrode 41 and the second auxiliary electrode 42. The first auxiliary electrode 41 covers a part of an upper surface of the first insulating layer 11 and extends from the upper surface of the first insulating layer 11 into the first via hole 111. In the first via hole 111, the first auxiliary electrode 41 covers a hole wall of the first via hole 111 and the source 21 exposed by the first via hole 111, so that the first auxiliary electrode 41 is in contact with and electrically connected to the source 21. That is, the first auxiliary electrode 41 completely covers the hole wall and the hole bottom of the first via hole 111, so that an orthographic projection of the first via hole 111 on the substrate 10 is located on an orthographic projection of the first auxiliary electrode 41 on the substrate 10. The second auxiliary electrode 42 covers another part of the upper surface of the first insulating layer 11. The material of the second conductive layer 40 includes at least one of indium tin oxide (ITO), indium zinc oxide (IZO), Cu, or Al. The thickness of the second conductive layer 40 ranges from 1000 angstroms to 5000 angstroms, such as 1000 angstroms, 2000 angstroms, 3000 angstroms, 4000 angstroms, or 5000 angstroms.

For convenience of description, the present disclosure defines that the surface of each structure away from the substrate 10 is the upper surface, the lower surface is opposite to the upper surface, and the side wall connects the upper surface and the lower surface. For example, the upper surface of the first insulating layer 11 refers to the surface of the first insulating layer 11 away from the substrate 10. The lower surface refers to the surface of the first insulating layer 11 opposite to the upper surface of the first insulating layer 11, and the lower surface of the first insulating layer 11 is in contact with the substrate 10 and the first conductive layer 20.

The active layer 30 is disposed on a side of the second conductive layer 40 away from the substrate 10. The source contact portion 31 and the drain contact portion 32 of the active layer 30 are both formed by conducting the active layer 30, and the source contact portion 31 and the drain contact portion 32 of the active layer 30 form conductor regions. The material of the active layer 30 includes indium gallium zinc oxide (IGZO), indium gallium zinc tin oxide (IGZTO), indium gallium oxide (IGO), IZO, lanthanide IZO, or the like. The thickness of the active layer 30 is smaller than the thickness of the second conductive layer 40. For example, the thickness of the active layer 30 ranges from 400 angstroms to 1000 angstroms, such as 400 angstroms, 500 angstroms, 600 angstroms, 700 angstroms, 800 angstroms, 900 angstroms, 1000 angstroms, or the like.

The source contact portion 31 is provided corresponding to the first auxiliary electrode 41, and the drain contact portion 32 is provided corresponding to the second auxiliary electrode 42. The channel portion 33 is provided corresponding to the first gap 401 between the first auxiliary electrode 41 and the second auxiliary electrode 42. The length L1 of the channel portion 33 is equal to the width D1 of the first gap 401, that is, the length L1 of the channel portion 33 depends on the width D1 of the first gap 401. In other words, by limiting the width D1 of the first gap 401 between the first auxiliary electrode 41 and the second auxiliary electrode 42, the length L1 of the channel portion 33 may be defined to realize a narrow channel, so that the size of the thin film transistor may be reduced and the PPI may be increased. The problem that the layout design space for the array substrate 100 is limited and it is difficult to realize high resolution may be improved. The length L1 of the channel portion 33 ranges from 0.5 microns to 3 microns, such as 0.5 microns, 0.8 microns, 1 micron, 1.2 microns, 1.5 microns, 1.8 microns, 2 microns, 2.3 microns, 2.6 microns, 2.9 microns, 3 microns, or the like.

The source contact portion 31 covers the upper surface of the first auxiliary electrode 41, and is in contact with and electrically connected to the first auxiliary electrode 41. The drain contact portion 32 covers the upper surface of the second auxiliary electrode 42, and is in contact with and electrically connected to the second auxiliary electrode 42. The source contact portion 31 further covers the upper surface of the first auxiliary electrode 41 located in the first via hole 111. The orthographic projection of the first via hole 111 on the substrate 10 is located in the orthographic projection of the source contact portion 31 on the substrate 10. In the first via hole 111, the first auxiliary electrode 41 is in contact with and electrically connected to the source 21. The source contact portion 31 is in contact with and electrically connected to the first auxiliary electrode 41, so that the source contact portion 31 is electrically connected to the source 21 through the first auxiliary electrode 41, and the risk of the source contact portion 31 climbing and disconnecting in the first via hole 111 may be reduced. In this way, by providing the first auxiliary electrode 41 and the second auxiliary electrode 42, it is possible to reduce the risk of the source contact portion 31 climbing and disconnecting in the first via hole 111 while realizing a narrow channel, reducing the size of the thin film transistor and increasing the PPI.

It should be noted that the thickness of the first insulating layer 11 is larger, and the thickness of the active layer 30 is smaller. The thickness of the active layer 30 is much smaller than the thickness of the first insulating layer 11. In condition that the aperture size of the first via hole 111 is small, since the thickness of the first insulating layer 11 is larger, the taper angle of the first via hole 111 is large, and when the active layer 30′ having a thin film thickness climbs in the first via hole 111, problems such as disconnection are likely to occur, and the reliability of electrical connection between the source contact portion 31 and the source 21 will be affected. In order to improve the problem that the active layer 30 is disconnected when climbing in the first via hole 111, the first via hole 111 having a larger aperture may be provided, for example, the aperture of the first via hole 111 is larger than 2 microns, but this will increase the occupied area of the first transistor.

However, in the embodiments of the present disclosure, by extending the first auxiliary electrode 41 into the first via hole 111 and causing the source contact portion 31 to cover the first auxiliary electrode 41 located in the first via hole 111, even if the source contact portion 31 is disconnected in the first via hole 111, the first auxiliary electrode 41 may fill the disconnected position of the source contact portion 31 and improve the reliability of the electrical connection between the source contact portion 31 and the source 21. Furthermore, the size of the thin film transistor may be further reduced, the occupied area of the first transistor may be reduced, and the PPI may be further increased.

The second insulating layer 12 is disposed on a side of the active layer 30 away from the substrate 10, and is provided corresponding to the channel portion 33. The material of the second insulating layer 12 includes an inorganic material, and for example, the second insulating layer 12 may be a single layer or a plurality of layers including at least one of tetraethyl orthosilicate, silicon nitride, silicon oxide, or the like. The thickness of the second insulating layer 12 ranges from 1000 angstroms to 3000 angstroms, such as 1000 angstroms, 1500 angstroms, 2000 angstroms, 2500 angstroms, 3000 angstroms, or the like.

The third conductive layer 50 is disposed on a side of the second insulating layer 12 away from the substrate 10. The third conductive layer 50 includes a gate 51 of the first transistor. The gate 51 is provided corresponding to the second insulating layer 12. The third conductive layer 50 may be formed as a plurality of layers or a single layer of a low resistance material such as Al, Ti, Mo, Cu, Ni, or an alloy thereof, or a material having high anti-corrosion properties. For example, the third conductive layer 50 may be a laminated structure of Moti/Cu, Ti/Cu/Ti, Ti/Ag/Ti, Ti/Al/Ti, Mo/Al/Mo, or the like. The thickness of the third conductive layer 50 ranges from 2000 angstroms to 8000 angstroms, such as 2000 angstroms, 3000 angstroms, 4000 angstroms, 5000 angstroms, 6000 angstroms, 7000 angstroms, 8000 angstroms, or the like.

The orthographic projection of the gate 51 on the substrate 10 covers the orthographic projection of the channel portion 33 on the substrate 10, that is, the orthographic projection of the channel portion 33 on the substrate 10 is located in the orthographic projection of the gate 51 on the substrate 10. The area of the orthographic projection of the channel portion 33 is smaller than the area of the orthographic projection of the gate 51. The channel portion 33 is located in the region defined by the first gap 401 between the first auxiliary electrode 41 and the second auxiliary electrode 42, so that the orthographic projection of the gate 51 on the substrate 10 further covers a part of the orthographic projection of the first auxiliary electrode 41 on the substrate 10 and a part of the orthographic projection of the second auxiliary electrode 42 on the substrate 10. That is, both the orthographic projection of the first auxiliary electrode 41 on the substrate 10 and the orthographic projection of the second auxiliary electrode 42 on the substrate 10 partially overlap the orthographic projection of the gate 51 on the substrate 10. In this way, there is no need to limit the size of the channel portion 33 by the size of the gate 51, which may reduce the difficulty of manufacturing the gate 51 and facilitate the implementation of the process. A part of the active layer 30 that is located in an overlapping region between the gate 51 and the first auxiliary electrode 41 and the second auxiliary electrode 42 does not serve as the channel portion 33 of the active layer 30. The channel portion 33 is located in the region that corresponds to the first gap 401 between the first auxiliary electrode 41 and the second auxiliary electrode 42.

Referring to FIG. 2, the array substrate 100 further includes a third insulating layer 13, a planarization layer 14, a common electrode 60, a fourth insulating layer 15, and a pixel electrode 70. The third insulating layer 13 is disposed on the side of the third conductive layer 50 away from the substrate 10. For example, the third insulating layer 13 covers the upper surface and sidewall of the gate 51, the sidewall of the second insulating layer 12, the upper surface and sidewall of the source contact portion 31, the upper surface and sidewall of the drain contact portion 32, and a part of the first insulating layer 11. The material of the third insulating layer 13 includes an inorganic material. for example, the third insulating layer 13 may be a single layer or a plurality of layers including at least one of tetraethyl orthosilicate, silicon nitride, silicon oxide, or the like.

The planarization layer 14 is disposed on a side of the third insulating layer 13 away from the substrate 10. The material of the planarization layer 14 includes an organic material. For example, the planarization layer 14 may be formed to include a resin such as polyacrylate, polyimide, a silica-based organic material, or the like.

The common electrode 60 is disposed on a side of the planarization layer 14 away from the substrate 10. The common electrode 60 may be formed of a transparent conductive material such as indium tin oxide (ITO), IZO, zinc oxide (ZnO), or indium oxide (In₂O₃).

The fourth insulating layer 15 is disposed on a side of the common electrode 60 away from the substrate 10. The fourth insulating layer 15 includes a third via hole 151 provided corresponding to the drain contact portion 32. The third via hole 151 penetrates the fourth insulating layer 15, the planarization layer 14, and the third insulating layer 13 to expose a part of the drain contact portion 32. The material of the fourth insulating layer 15 includes an inorganic material. For example, the fourth insulating layer 15 may be a single layer or a plurality of layers including at least one of tetraethyl orthosilicate, silicon nitride, silicon oxide, or the like.

The pixel electrode 70 is disposed on the side of the fourth insulating layer 15 away from the substrate 10. The pixel electrode 70 is in contact with and electrically connected to the drain contact portion 32 through the third via hole 151, that is, a part of the pixel electrode 70 is located in the third via hole 151 and is in contact with and electrically connected to the drain contact portion 32 exposed by the third via hole 151. The pixel electrode 70 is provided opposite to the common electrode 60. The material of the pixel electrode 70 may be the same as that of the common electrode 60. For example, the pixel electrode 70 may be formed of a transparent conductive material such as ITO, IZO, ZnO, or In₂O₃.

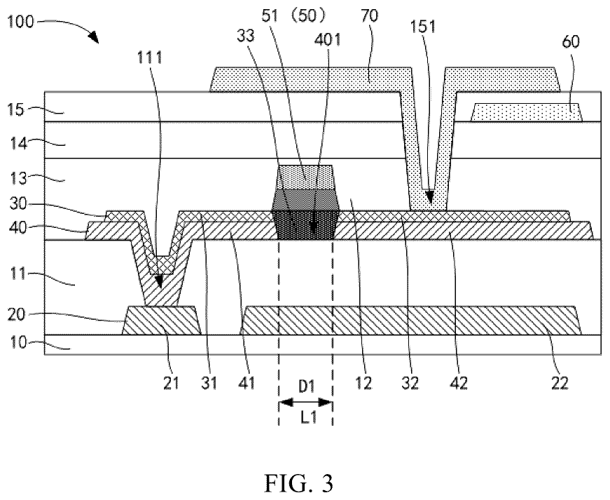

Referring to FIG. 3, FIG. 3 is a second schematic cross-sectional view of the array substrate 100 provided by some embodiments of the present disclosure, the difference between the embodiment shown in FIG. 3 and the embodiment shown in FIG. 2 is that, the orthographic projection of the gate 51 on the substrate 10 coincides with the orthographic projection of the channel portion 33 on the substrate 10. Please refer to the above embodiments for other detail descriptions, and details are not further repeated herein.

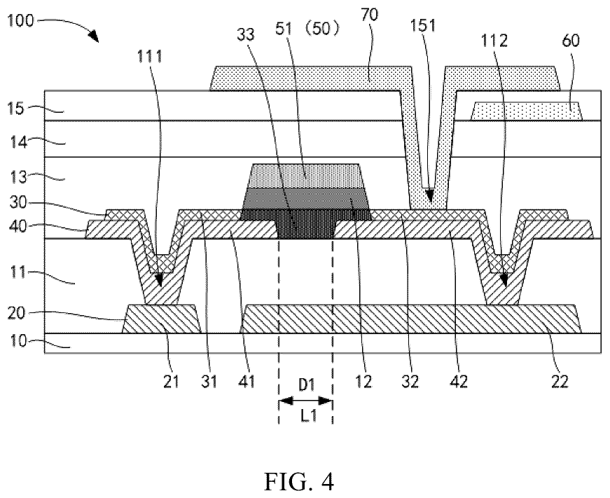

Referring to FIG. 4, FIG. 4 is a third schematic cross-sectional view of the array substrate 100 provided by some embodiments of the present disclosure, the difference between the embodiment shown in FIG. 4 and the embodiment shown in FIG. 2 is that, the first insulating layer 11 is provided with a second via hole 112 corresponding to the light shielding electrode 22, and a part of the second auxiliary electrode 42 and a part of the drain contact portion 32 are located in the second via hole 112 and electrically connected to the light shielding electrode 22 to improve the stability of the first transistor and reduce the risk of the drain contact portion 32 climbing and breaking in the second via hole 112.

Specifically, the second auxiliary electrode 42 covers another part of the upper surface of the first insulating layer 11 and extends from the upper surface of the first insulating layer 11 into the second via hole 112. In the second via hole 112, the second auxiliary electrode 42 covers the hole wall of the second via hole 112 and a part of the light shielding electrode 22 exposed by the second via hole 112, so that the second auxiliary electrode 42 is in contact with and is electrically connected to the light shielding electrode 22. That is, the second auxiliary electrode 42 completely covers the hole wall and the hole bottom of the second via hole 112, so that the orthographic projection of the second via hole 112 on the substrate 10 is located in the orthographic projection of the second auxiliary electrode 42 on the substrate 10.

The drain contact portion 32 covers the upper surface of the second auxiliary electrode 42, and is in contact with and electrically connected to the second auxiliary electrode 42. The drain contact portion 32 further covers the upper surface of the second auxiliary electrode 42 located in the second via hole 112. In the second via hole 112, the second auxiliary electrode 42 is in contact with and electrically connected to the light shielding electrode 22, and the drain contact portion 32 is in contact with and electrically connected to the second auxiliary electrode 42, so that the drain contact portion 32 is electrically connected to the light shielding electrode 22 through the second auxiliary electrode 42. The risk of the drain contact portion 32 climbing and disconnecting in the second via hole 112 may be reduced. Please refer to the above embodiments for other detail descriptions, and details are not further repeated herein.

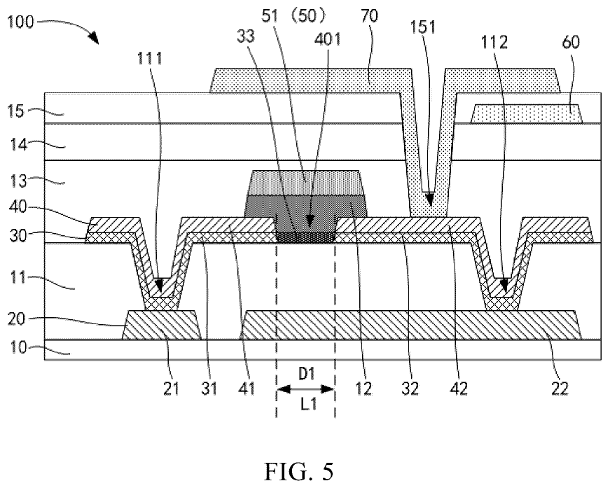

Referring to FIG. 5, FIG. 5 is a fourth schematic cross-sectional view of the array substrate 100 provided by some embodiments of the present disclosure, the difference between the embodiment shown in FIG. 5 and the embodiment shown in FIG. 4 includes that, the second conductive layer 40 is disposed on a side of the active layer 30 away from the substrate 10, and a part of the source contact portion 31 is located in the first via hole 111 and is electrically connected to the source 21.

Specifically, the active layer 30 covers the upper surface of the first insulating layer 11, and extends from the upper surface of the first insulating layer 11 into the first via hole 111 and the second via hole 112. More specifically, the source contact portion 31 covers a part of the upper surface of the first insulating layer 11 and extends from the upper surface of the first insulating layer 11 into the first via hole 111. In the first via hole 111, the source contact portion 31 covers the hole wall of the first via hole 111 and a part of the source 21 exposed by the first via hole 111, so that the source contact portion 31 is in contact with and is electrically connected to the source 21. That is, the source contact portion 31 completely covers the hole wall and the hole bottom of the first via hole 111, so that the orthographic projection of the first via hole 111 on the substrate 10 is located in the orthographic projection of the first via hole 111 on the substrate 10.

Correspondingly, the drain contact portion 32 covers another part of the upper surface of the first insulating layer 11 and extends from the upper surface of the first insulating layer 11 into the second via hole 112. In the second via hole 112, the drain contact portion 32 covers the hole wall of the second via hole 112 and a part of the light shielding electrode 22 exposed by the second via hole 112, so that the drain contact portion 32 is in contact with and electrically connected to the light shielding electrode 22 through the second via hole 112.

The second conductive layer 40 is disposed on a side of the active layer 30 away from the substrate 10. The second conductive layer 40 includes a first auxiliary electrode 41 and a second auxiliary electrode 42 disposed at intervals. The channel portion 33 of the active layer 30 covers the upper surface of the first insulating layer 11 and is disposed corresponding to the first gap 401 between the first auxiliary electrode 41 and the second auxiliary electrode 42. The length L1 of the channel portion 33 is equal to the width D1 of the first gap 401. That is, the length L1 of the channel portion 33 depends on the width D1 of the first gap 401. In other words, by limiting the width D1 of the first gap 401 between the first auxiliary electrode 41 and the second auxiliary electrode 42, the length L1 of the channel portion 33 may be defined to realize a narrow channel, so that the size of the thin film transistor may be reduced and the PPI may be increased. The problem that the layout design space for the array substrate 100 is limited and it is difficult to realize high resolution may be improved.

The first auxiliary electrode 41 covers the upper surface of the source contact portion 31. The second auxiliary electrode 42 covers the upper surface of the drain contact portion 32. The first auxiliary electrode 41 further covers the upper surface of the source contact portion 31 located in the first via hole 111. In the first via hole 111, the source contact portion 31 is in contact with and electrically connected to the source 21, and the first auxiliary electrode 41 is in contact with and electrically connected to the source contact portion 31, so that the risk of the source contact portion 31 climbing and disconnecting in the first via hole 111 may be reduced. Correspondingly, the second auxiliary electrode 42 covers the upper surface of the drain contact portion 32 located in the second via hole 112. In the second via hole 112, the drain contact portion 32 is in contact with and electrically connected to the light shielding electrode 22, and the second auxiliary electrode 42 is in contact with and electrically connected to the drain contact portion 32, so that the risk of the drain contact portion 32 climbing and disconnecting in the second via hole 112 may be reduced. In this way, by providing the second conductive layer 40 including the first auxiliary electrode 41 and the second auxiliary electrode 42 on the active layer 30, it is possible to reduce the risk of the source contact portion 31 climbing and disconnecting in the first via hole 111 and the risk of the drain contact portion 32 climbing and disconnecting in the second via hole 112 while realizing a narrow channel, reducing the size of the thin film transistor, and increasing the pixel density.

Further, the difference between the embodiment shown in FIG. 5 and the embodiment shown in FIG. 4 includes that, the second insulating layer 12 covers a part of the upper surface and a side wall of the first auxiliary electrode 41 and a part of the upper surface and a side wall of the second auxiliary electrode 42. The pixel electrode 70 is in contact with and electrically connected to the second auxiliary electrode 42 through the third via hole 151, that is, the third via hole 151 exposes a part of the second auxiliary electrode 42, and a part of the pixel electrode 70 is located in the third via hole 151, and is in contact with and electrically connected to the second auxiliary electrode 42 exposed by the third via hole 151, so that the contact impedance between the pixel electrode 70 and the drain contact portion 32 may be reduced, and the stability of the electrical connection between the pixel electrode 70 and the drain contact portion 32 may be improved. Please refer to the above embodiments for other detail descriptions, and details are not further repeated herein.

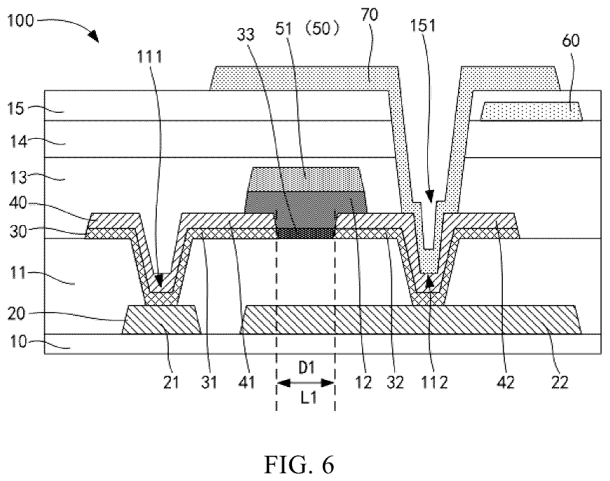

Referring to FIG. 6, FIG. 6 is a fifth schematic cross-sectional view of the array substrate 100 provided by some embodiments of the present disclosure, the difference between the embodiment shown in FIG. 6 and the embodiment shown in FIG. 5 is that, the third via hole 151 corresponds to the second via hole 112, and the pixel electrode 70 located in the third via hole 151 is further located in the second via hole 112 to increase the contact area between the pixel electrode 70 and the second auxiliary electrode 42. The contact impedance between the pixel electrode 70 and the drain contact portion 32 may be further reduced, and the stability of electrical connection between the pixel electrode 70 and the drain contact portion 32 may be further improved. Please refer to the above embodiments for other detail descriptions, and details are not further repeated herein.

Based on the same inventive concept, the present disclosure further provides a display panel including an array substrate 100 according to one of the foregoing embodiments. The display panel includes a liquid crystal display panel, an organic light emitting diode display panel, or another type of display panel.

In summary, the present disclosure provides the array substrate and the display panel. The array substrate includes the substrate and the first conductive layer, the first insulating layer, the second conductive layer and the active layer disposed on the substrate. The second conductive layer includes a first auxiliary electrode and a second auxiliary electrode arranged at intervals. The first gap between the first auxiliary electrode and the second auxiliary electrode may define the length of a channel portion of the active layer to achieve a narrow channel, so that the size of a thin film transistor may be reduced and the PPI may be increased. The problem that the layout design space for the array substrate 100 is limited and it is difficult to realize high resolution may be improved. Furthermore, the first auxiliary electrode and the source contact portion of the active layer extend into the first via hole of the first insulating layer and are electrically connected to the source of the first conductive layer. The first auxiliary electrode located in the first via hole may reduce the risk of the source contact portion climbing and disconnecting in the first via hole.

In the foregoing embodiments, the description of each of the embodiments has respective focuses. For a part that is not described in detail in an embodiment, reference may be made to relevant descriptions in other embodiments.

The embodiments of the present disclosure are described in detail above. The principle and implementations of the present disclosure are described in this specification by using specific examples. The description about the foregoing embodiments is merely provided to help understand the method and core ideas of the present disclosure. Those skilled in the art should understand that they may still make modifications to the technical solutions described in the foregoing embodiments or make equivalent replacements to some technical features thereof, without departing from the scope of the technical solutions of the embodiments of the present disclosure.

What is claimed is:

1. An array substrate, comprising:
a substrate;
a first conductive layer disposed on a side of the substrate and comprising a source and a light shielding electrode disposed at intervals;
a first insulating layer disposed on a side of the first conductive layer away from the substrate and provided with a first via hole corresponding to the source;
a second conductive layer disposed on a side of the first insulating layer away from the substrate and comprising a first auxiliary electrode and a second auxiliary electrode disposed at intervals, wherein a first gap is provided between the first auxiliary electrode and the second auxiliary electrode;
an active layer disposed on the side of the first insulating layer away from the substrate and comprising a source contact portion, a drain contact portion and a channel portion, wherein the channel portion is connected between the source contact portion and the drain contact portion, the source contact portion corresponds to the first auxiliary electrode and is electrically connected to the first auxiliary electrode, the drain contact portion corresponds to the second auxiliary electrode and is electrically connected to the second auxiliary electrode, and the channel portion corresponds to the first gap and is provided opposite to at least a part of the light shielding electrode;
a second insulating layer disposed on a side of the active layer away from the substrate; and
a third conductive layer disposed on a side of the second insulating layer away from the substrate and comprising a gate corresponding to the channel portion;
wherein a part of the first auxiliary electrode and a part of the source contact portion are located in the first via hole and electrically connected to the source; and a channel length of the channel portion is equal to a width of the first gap.

2. The array substrate of claim 1, wherein an orthographic projection of the first via hole on the substrate is located in an orthographic projection of the first auxiliary electrode on the substrate, and the orthographic projection of the first via hole on the substrate is located in an orthographic projection of the source contact portion on the substrate.

3. The array substrate of claim 2, wherein the active layer is disposed on a side of the second conductive layer away from the substrate, and the part of the first auxiliary electrode is connected to and in contact with the source.

4. The array substrate of claim 2, wherein the second conductive layer is disposed on a side of the active layer away from the substrate, and the part of the source contact portion is connected to and in contact with the source.

5. The array substrate of claim 2, wherein a material of the second conductive layer comprises at least one of indium tin oxide (ITO), indium zinc oxide (IZO), Cu, or Al.

6. The array substrate of claim 1, wherein an orthographic projection of the gate on the substrate coincides with an orthographic projection of the channel portion on the substrate.

7. The array substrate of claim 1, wherein an area of an orthographic projection of the channel portion on the substrate is smaller than an area of an orthographic projection of the gate on the substrate.

8. The array substrate of claim 1, wherein an orthographic projection of the gate on the substrate partially overlaps an orthographic projection of the first auxiliary electrode on the substrate and an orthographic projection of the second auxiliary electrode on the substrate, respectively.

9. The array substrate of claim 1, wherein an orthographic projection of the channel portion on the substrate is in an orthographic projection of the gate on the substrate, and the orthographic projection of the gate on the substrate partially overlaps an orthographic projection of the first auxiliary electrode on the substrate and an orthographic projection of the second auxiliary electrode on the substrate.

10. The array substrate of claim 9, wherein a length of the channel portion ranges from 0.5 microns to 3 microns.

11. The array substrate of claim 1, wherein the first insulating layer is provided with a second via hole corresponding to the light shielding electrode, and a part of the second auxiliary electrode and a part of the drain contact portion are located in the second via hole and electrically connected to the light shielding electrode.

12. The array substrate of claim 11, wherein the array substrate further comprises:
a third insulating layer disposed on a side of the third conductive layer away from the substrate;
a planarization layer disposed on a side of the third insulating layer away from the substrate;
a common electrode disposed on a side of the planarization layer away from the substrate;
a fourth insulating layer disposed on a side of the common electrode away from the substrate, and provided with a third via hole corresponding to the drain contact portion; and
a pixel electrode disposed on a side of the fourth insulating layer away from the substrate and disposed opposite to the common electrode, wherein a part of the pixel electrode is disposed in the third via hole and electrically connected to the drain contact portion.

13. The array substrate of claim 12, wherein the third via hole corresponds to the second via hole, and the part of the pixel electrode located in the third via hole is further located in the second via hole.

14. The array substrate of claim 1, wherein a thickness of the active layer is less than a thickness of the second conductive layer.

15. An array substrate, comprising:
a substrate;
a first conductive layer disposed on a side of the substrate and comprising a source;
a first insulating layer disposed on a side of the first conductive layer away from the substrate and provided with a first via hole corresponding to the source;
a second conductive layer disposed on a side of the first insulating layer away from the substrate and comprising a first auxiliary electrode and a second auxiliary electrode disposed at intervals, wherein a first gap is provided between the first auxiliary electrode and the second auxiliary electrode; and
an active layer disposed on the side of the first insulating layer away from the substrate and comprising a source contact portion, a drain contact portion and a channel portion, wherein the channel portion is connected between the source contact portion and the drain contact portion, the source contact portion corresponds to the first auxiliary electrode and is electrically connected to the first auxiliary electrode, the drain contact portion corresponds to the second auxiliary electrode and is electrically connected to the second auxiliary electrode, and the channel portion corresponds to the first gap;
wherein a part of the first auxiliary electrode and a part of the source contact portion are located in the first via hole and electrically connected to the source; and a channel length of the channel portion is equal to a width of the first gap.

16. The array substrate of claim 15, wherein the first conductive layer further comprises a light shielding electrode spaced apart from the source, and an orthographic projection of the channel portion on the substrate is located in an orthographic projection of the light shielding electrode on the substrate.

17. The array substrate of claim 15, wherein the array substrate further comprises:
a second insulating layer disposed on a side of the active layer away from the substrate; and
a third conductive layer disposed on a side of the second insulating layer away from the substrate and comprising a gate corresponding to the channel portion.

18. The array substrate of claim 15, wherein an orthographic projection of the first via hole on the substrate is located in an orthographic projection of the first auxiliary electrode on the substrate, and the orthographic projection of the first via hole on the substrate is located in an orthographic projection of the source contact portion on the substrate.

19. The array substrate of claim 18, wherein the active layer is disposed on a side of the second conductive layer away from the substrate, and the part of the first auxiliary electrode is connected to and in contact with the source; or
the second conductive layer is disposed on a side of the active layer away from the substrate, and the part of the source contact portion is connected to and in contact with the source.

20. A display panel, comprising an array substrate, wherein the display panel comprises:
a substrate;
a first conductive layer disposed on a side of the substrate and comprising a source and a light shielding electrode disposed at intervals;
a first insulating layer disposed on a side of the first conductive layer away from the substrate and provided with a first via hole corresponding to the source;
a second conductive layer disposed on a side of the first insulating layer away from the substrate and comprising a first auxiliary electrode and a second auxiliary electrode disposed at intervals, wherein a first gap is provided between the first auxiliary electrode and the second auxiliary electrode; and
an active layer disposed on a side of the first insulating layer away from the substrate and comprising a source contact portion, a drain contact portion and a channel portion, wherein the channel portion is connected between the source contact portion and the drain contact portion, the source contact portion corresponds to the first auxiliary electrode and is electrically connected to the first auxiliary electrode, the drain contact portion corresponds to the second auxiliary electrode and is electrically connected to the second auxiliary electrode, and the channel portion corresponds to the first gap and is provided opposite to at least a part of the light shielding electrode;
a second insulating layer disposed on a side of the active layer away from the substrate; and
a third conductive layer disposed on a side of the second insulating layer away from the substrate and comprising a gate corresponding to the channel portion;
wherein a part of the first auxiliary electrode and a part of the source contact portion are located in the first via hole and electrically connected to the source; and a channel length of the channel portion is equal to a width of the first gap.
